(19) United States
(12) Patent Application Publication
(10) Pub. No.: US 2014/0202946 A1
(43) Pub. Date: Jul. 24, 2014

(54) PIPING JOINT AND SEMICONDUCTOR MANUFACTURING APPARATUS

(71) Applicant: KABUSHIKI KAISHA TOSHIBA, Tokyo (JP)

(72) Inventors: Noriyuki ASAMI, Yokkaichi-Shi (JP); Koudai KITAMURA, Yokkaichi-Shi (JP); Katsuhiko TACHIBANA, Yokkaichi-Shi (JP); Kenzo KUGIMIYA, Yokkaichi-Shi (JP); Nobuhide YAMADA, Yokkaichi-Shi (JP)

(73) Assignee: KABUSHIKI KAISHA TOSHIBA, Tokyo (JP)

(21) Appl. No.: 13/898,747

(22) Filed: May 21, 2013

Related U.S. Application Data
(60) Provisional application No. 61/755,065, filed on Jan. 22, 2013.

(51) Int. Cl. H01L 21/67; F16L 55/02; B01D 35/02

(52) U.S. Cl. CPC H01L 21/6715; B01D 35/02; F16L 55/02
USPC 210/243; 285/45

(57) ABSTRACT

The piping joint according to the present embodiment includes a joint part that joins a plurality of pipes for transporting a medium to one another. At least one conductive line is provided between the pipes so as to extend over cross-sections of the pipes. A ground part grounds the conductive line. The conductive line removes electric charges from the medium via the ground part.

### CROSS REFERENCE TO RELATED APPLICATIONS

This application is based upon and claims the benefit of priority from the prior U.S. Patent Application No. 61/755,065, filed on Jan. 22, 2013, the entire contents of which are incorporated herein by reference.

### FIELD

The embodiments of the present invention relate to a piping joint and a semiconductor manufacturing apparatus.

### BACKGROUND

A semiconductor manufacturing apparatus such as a film formation apparatus includes pipes for transporting a chemical used in the manufacturing of semiconductor devices. A filter device is attached to the pipes so as to filter the chemical supplied to the semiconductor devices. Examples of the chemical used in the semiconductor manufacturing apparatus include an insoluble liquid that has a high electrical resistance because of a low water content. When such a chemical is filtered by a filter, the chemical flows in one of the pipes in a state of being electrically charged by static electricity generated by a friction between the chemical and the filter. When the electrically-charged chemical flows in the pipe, the potential difference between the inside and outside of the pipe generates a surge to often generate pin holes in the pipe. When the pin holes are generated in the pipe, there is a problem that the chemical leaks out of the pipe.

To deal with such a problem, it is considered to increase the surface area of the filter so as to reduce a friction between the chemical and the filter. However, in this case, the liquid is still electrically charged although the electrification of the liquid decreases to some extent. Furthermore, the size of the filter is made large, which increases the cost of the filter.

It is also considered to change the material of each pipe to a conductive material and ground the pipe. However, many conductive materials such as metal are non-transparent and less flexible. In this case, the interior of the pipe is invisible and it is difficult to extend the pipe. The use of a transparent and flexible conductive material for a pipe is expensive and is unrealistic.

Furthermore, it is considered to wind an earth tape around the outer circumference of each pipe. However, a surge is generated between the chemical in the pipe and the earth tape outside the pipe, resulting in pin holes.

### BRIEF DESCRIPTION OF THE DRAWINGS

FIG. 1 shows a configuration of a semiconductor manufacturing apparatus 1 according to an embodiment;

FIG. 2 is a cross-sectional view taken along a line 2-2 of FIG. 1 and shows a configuration of the piping joint 40; and

FIG. 3 is a graph showing an electrification amount of the medium MD.

### DETAILED DESCRIPTION

The piping joint according to the present embodiment includes a joint part that joins a plurality of pipes for transporting a medium to one another. At least one conductive line is provided between the pipes so as to extend over cross-sections of the pipes. A ground part grounds the conductive line. The conductive line removes electric charges from the medium via the ground part.

Embodiments will now be explained with reference to the accompanying drawings. The present invention is not limited to the embodiments.

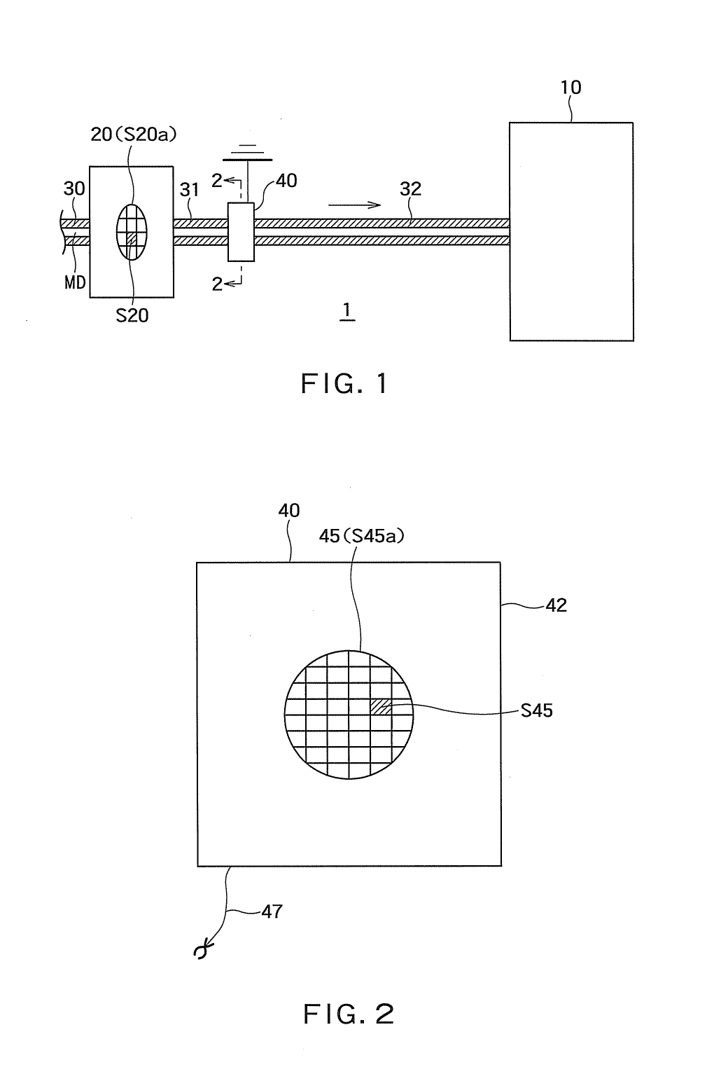

FIG. 1 shows a configuration of a semiconductor manufacturing apparatus 1 according to an embodiment. The semiconductor manufacturing apparatus 1 includes a processing main body 10, a filter 20, pipes 30 to 32, and a piping joint 40.

For example, the semiconductor manufacturing apparatus 1 is a film formation apparatus, an etching apparatus, a resist coater apparatus, an SOD (Spin On Dielectric) coater apparatus, or a cleaning apparatus used in the process of manufacturing a semiconductor device. Therefore, the processing main body 10 is a unit that performs film formation, etching, resist coating, SOD coating, or cleaning (hereinafter, simply “semiconductor process”). For the processing main body 10 to perform the above semiconductor process, it is necessary for the pipes 30 to 32 to transport a medium MD used in the semiconductor process to the processing main body 10.

The medium MD is a liquid used in the semiconductor process and is a petroleum-based or naphtha-based medium. Such an insoluble (nonaqueous) medium MD has a property to tend to be electrically charged because the medium MD hardly contains water (a water content of 0.5 ppm or less, for example). Specifically, the medium MD is a chemical, a resist, or the like such as polysilazane used for SOD.

The pipe 30 transports the medium MD from a medium storage unit (not shown) present either inside or outside of the semiconductor manufacturing apparatus 1 to the filter 20. The pipe 31 transports the medium MD from the filter 20 to the piping joint 40. The pipe 32 transports the medium MD from the piping joint 40 to the processing main body 40. The pipes to 32 are formed by using a transparent, electrically insulating, and flexible material. For example, each of the pipes 30 to 32 is formed by using a Teflon tube (PFA tube).

The filter 20 filters the medium MD so as to remove impurities such as waste and dust or particles contained in the medium MD transported by the pipe 30. For example, the filter 20 is a mesh filter formed by using a material such as PTFT (polytetrafluoroethylene, so-called “Teflon”). Although not limited to a specific size, the size (area) of each mesh of the filter 20 is determined by conditions such as the area of the entire filter 20 and the sizes of the impurities. For example, when the area of each mesh of the filter 20 is small (when each mesh of the filter 20 is fine), the filter 20 can remove relatively small impurities but a flow velocity of the medium MD possibly decreases. That is, in this case, a frictional resistance (a fluid friction) of the medium MD increases, and the flow of the medium MD becomes slow down. On the other hand, when the area of each mesh of the filter 20 is large (when each mesh of the filter 20 is coarse), the frictional resistance of the medium MD decreases and the flow velocity of the medium MD is kept to high. However, the filter 20 is unable to remove relatively small impurities. Therefore, it is considered to decrease the area of each mesh of the filter 20 and to increase the area of the entire filter 20. Accordingly, the filter 20 does not impede the flow of the medium MD while removing relatively small impurities. However, to increase the area of the entire filter 20 means to increase the size of the entire filter 20 and to increase the cost of the filter 20.

As described above, when the filter 20 filters the medium MD, the medium MD tends to be electrically charged by a friction with the filter 20. For example, when the filter 20 is made of Teflon and the medium MD is made of polysilazane, the filter 20 tends to accumulate negative charges. In this case, positive charges remain in the medium MD and the medium MD is positively charged. Even when the area of the entire filter 20 increases, the medium MD is electrically charged by a friction between the medium MD and the filter 20. The polarity of the electric charges accumulated in the medium MD possibly varies depending on a magnitude of a work function between the material of the filter 20 and that of the medium MD. Therefore, the medium MD is may be positively charged by a friction with the filter 20. Electrification and electric charge removal of and from the medium MD are described later.

The piping joint 40 is provided to join the pipes 31 and 32 for transporting the medium MD to each other and to remove electric charges from the medium MD.

FIG. 2 is a cross-sectional view taken along a line 2-2 of FIG. 1 and shows a configuration of the piping joint 40. The piping joint 40 includes a joint part 42, a conductive line 45, and a ground part 47. The joint part 42 joins the pipe 31 to the pipe 32 liquid-tightly so that the medium MD does not leak out of the pipes 31 and 32. The structure of the joint part 42 is not specifically limited to any type. For example, the joint part 42 can be inserted into the pipes 31 and 32 and joins the pipes 31 and 32 to each other by clamping forces of the pipes 31 and 32 themselves. Alternatively, the joint part 42 can be inserted into the pipes 31 and 32 and a hose band (not shown) can clamp the pipes 31 and 32 from outside.

The material of the joint part 42 is also not specifically limited to any type. However, the material of the joint part 42 is preferably one that can join the pipes 31 and 32 to each other liquid-tightly and that does not react to the medium MD. For example, the joint part 42 is formed by using metal or plastic (Teflon, for example). As described later, when the ground part 47 grounds the conductive line 45 via the joint part 42, the joint part 42 is preferably formed by using a conductive material. Furthermore, the joint part 42 is a portion in contact with the medium MD and, on the assumption that the medium MD is supplied to a semiconductor substrate, the material of the joint part 42 is preferably not an element (Cu, Al, or the like) that becomes a contaminant source for the semiconductor device. However, if the material of the joint part 42 does not easily dissolve into the medium MD, Cu, Al, or the like can be used as the material of the joint part 42. The conductive line 45 is provided between the pipes 31 and 32 to traverse cross-sections of the pipes 31 and 32 through which the medium MD passes. For example, the conductive line 45 suffices to be one conductive line extending to traverse the cross-sections of the pipes 31 and 32. Even in this case, the conductive line 45 can remove electric charges from the medium MD to some extent. However, in this case, because of a small contact area between the conductive line 45 and the medium MD, the conductive line 45 may not be able to sufficiently remove electric charges from the medium MD. Therefore, the conductive line 45 is preferably provided in plural numbers extending to traverse the cross-sections of the pipes 31 and 32 through which the medium MD passes so as to sufficiently remove electric charges from the medium MD. For example, the conductive line 45 is preferably a mesh conductor extending over the cross-sections of the pipes 31 and 32 between the pipes 31 and 32 as shown in FIG. 2. Because this can increase the contact area between the conductive line 45 and the medium MD, the conductive line 45 can sufficiently remove electric charges from the medium MD.

The conductive line 45 is formed by a conductive material and can be formed by using stainless steel, tungsten, molybdenum, or conductive plastic, for example. However, copper, aluminum, or the like that possibly becomes the contaminant source for the semiconductor device is inappropriate as the material of the conductive line 45.

When the joint part 42 is formed by using the conductive material, the conductive line 45 is preferably electrically connected to the joint part 42. This enables the joint part 42 to electrically connect the conductive line 45 to the ground part 47. In this case, the ground part 47 suffices to be connected to the joint part 42 and does not need to be directly connected to the conductive line 45. The conductive line 45 can be formed integrally with the joint part 42. It is thereby possible for the joint part 42 to ensure electrically connecting the conductive line 45 to the ground part 47. This also facilitates forming the piping joint 40.

On the other hand, when the joint part 42 is formed by using a nonconductive material, the ground part 47 is directly connected to the conductive line 45.

The ground part 47 is electrically connected to the conductive line 45 so as to ground the conductive line 45. The ground part 47 can flow the electric charges removed from the medium MD to a ground by connecting the conductive line 45 to the ground. The ground part 47 is formed by a conductive material and can be formed by using stainless steel, tungsten, molybdenum, conductive plastic, copper, or aluminum, for example. The ground part 47 can be formed by using the same material as that used for forming the conductive line 45 or the joint part 42. In this case, the ground part 47 can be formed integrally with the conductive line 45 or the joint part 42.

The piping joint 40 is arranged downstream of the filter 20 and near the filter 20. The piping joint 40 can thereby remove electric charges from the medium MD electrically charged by the filter 20.

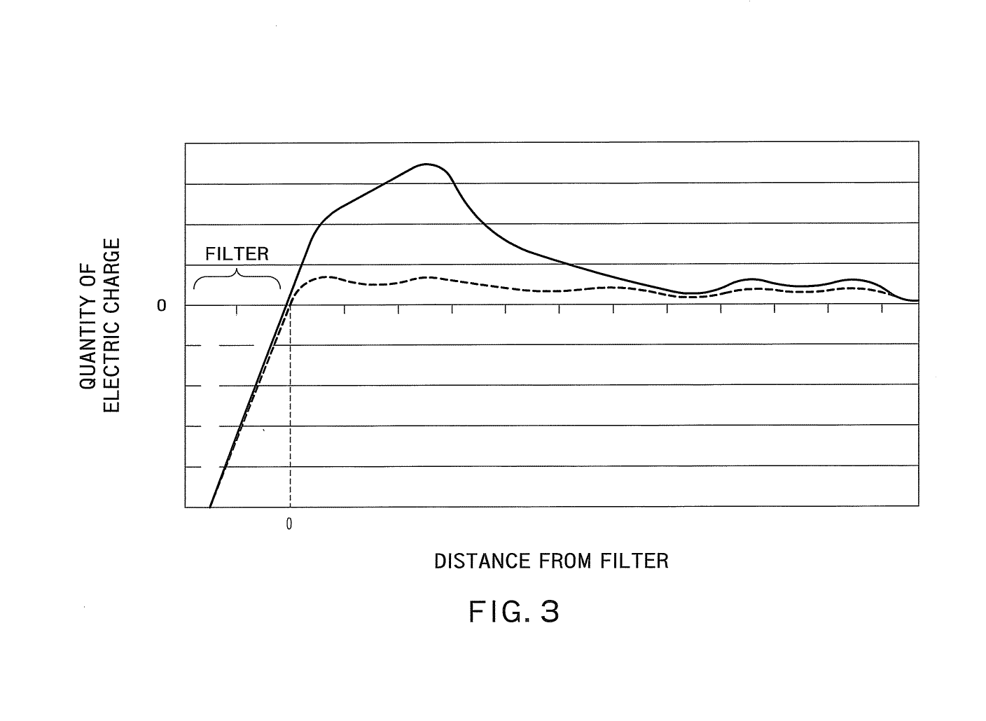

FIG. 3 is a graph showing an electrification amount of the medium MD. In the graph of FIG. 3, a vertical axis indicates an amount of electric charges (an electrification amount) of the medium MD or the filter 20, and a horizontal axis indicates a distance from the filter 20. A solid graph indicates the electrification amount in a case where the piping joint 40 is not provided between the pipes 31 and 32. A dashed graph indicates the electrification amount in a case where the piping joint 40 is provided between the pipes 31 and 32.

The filter 20 accumulates negative electric charges from the medium MD after the medium MD passes through the filter 20. Conversely, therefore, the medium MD is positively charged right after passing through the filter 20. Because the electric charges of the medium MD are accumulated in the pipe 31 by the contact of the medium MD with the pipe 31, an internal voltage of the pipe 31 reaches a few kilovolts near the filter 20, which possibly generates a surge.

In this connection, the piping joint 40 according to the present embodiment is arranged downstream of the filter 20 and near the filter 20. The piping joint 40 can thereby remove electric charges from the medium MD electrically charged right after passing through the filter 20. In this way, the piping joint or the semiconductor manufacturing apparatus 1 that includes the piping joint 40 can suppress the generation of pin holes in the pipe 32 by removing electric charges from the medium MD within the pipes 31 and 32.

When the conductive line 45 is meshed, the conductive line 45 preferably does not impede the flow of the medium MD. Because the conductive line 45 is provided downstream of the filter 20, it is preferable that the frictional resistance of the medium MD in the conductive line 45 is lower than that of the medium MD in the filter 20 and that the conductive line 45 does not impede the flow of the medium MD. As described above, the area of the filter 20 is often larger than a cross-sectional area (an area of the conductive line 45) of the pipes 31 and 32 so as not to slow down the flow of the medium MD. Therefore, a cross-sectional area S45a of a portion of the conductive line 45 through which the medium MD passes as shown in FIG. 2 is generally smaller than a cross-sectional area S20a of a portion of the filter 20 through which the medium MD passes as shown in FIG. 1. In such a case, when each mesh of the conductive line 45 is finer than that of the filter 20 (an area S45 of each mesh of the conductive line 45 is smaller than an area S20 of each mesh of the filter 20), the fluid friction of the medium MD in the conductive line 45 is higher than that of the medium MD in the filter 20. Therefore, it is preferable that the area S45 of each mesh of the conductive line 45 is at least larger than the area S20 of each mesh of the filter 20. It is thereby possible to make the fluid friction of the medium MD in the conductive line 45 lower than that of the medium MD in the filter 20.

Furthermore, when the cross-sectional area of the pipes 31 and 32 (the area S45a of the entire mesh conductive line 45) is smaller than the area S20a of the filter 20, a flow velocity of the medium MD passing through the conductive line 45 is higher than that of the medium MD passing through the filter 20. Therefore, it is necessary to increase the area S45 of each mesh of the conductive line 45 in proportion to the flow velocity of the medium MD so as not to slow down the flow of the medium MD in the conductive line 45. In this case, it suffices to set a ratio (S45/S20) of the area S45 of each mesh of the conductive line 45 to the area S20 of each mesh of the filter 20 to be almost equal to or higher than a ratio (V45/V20) of a flow velocity V45 of the medium MD passing through the conductive line 45 to a flow velocity V20 of the medium MD passing through the filter 20. Accordingly, the fluid friction of the medium MD in the conductive line 45 can be made lower than that of the medium MD in the filter 20 and the conductive line 45 does not impede the flow of the medium MD.

Further, the ratio (V45/V20) of the flow velocity V45 to the flow velocity V20 correlates to a reciprocal (S20a/S45a) of the ratio of the entire area S45a of the entire mesh of the conductive line 45 to the area S20a of the filter 20. For example, when the area S45a of the entire conductive line 45 decreases, the flow velocity V45 increases in inverse proportion to the area S45a. When the area S20a of the filter 20 decreases, the flow velocity V20 increases in inverse proportion to the area S20a. Therefore, in other words, the ratio (S45/S20) of the area S45 of each mesh of the conductive line 45 to the area S20 of each mesh of the filter 20 is preferably almost equal to or higher than the reciprocal (S20a/S45a) of the ratio of the entire area S45a of the entire mesh of the conductive line 45 to the entire area S20a of the filter 20. It is thereby possible to make the fluid friction of the medium MD in the conductive line 45 lower than that of the medium MD in the filter 20 and the conductive line 45 does not impede the flow of the medium MD.

In this way, the piping joint 40 and the semiconductor manufacturing apparatus 1 according to the present embodiment can remove electric charges from the medium MD downstream of the filter 20. By allowing the piping joint 40 to remove electric charges from the medium MD, it is possible to suppress a surge in the pipe 32 and the generation of pin holes in the pipe 32. The present embodiment can attain the above effects even when the pipes 30 to 32 are transparent and flexible insulating pipes. Because the pipes 30 to 32 are transparent, a user can visually recognize whether air bubbles are present in the medium MD. Because the pipes 30 to 32 are flexible, the pies 30 to 32 are easy to extend and the semiconductor manufacturing apparatus 1 and the filter 20 can be easily installed.

Furthermore, by making the area S45 of each mesh of the conductive line 45 larger than the area S20 of each mesh of the filter 20, the fluid friction of the medium MD in the conductive line 45 can be made lower than that of the medium MD in the filter 20.

Further, by making the mesh area ratio (S45/S20) almost equal to or higher than the ratio (S20a/S45a) of the area S20a of the filter 20 to the area S45a of the entire mesh of the conductive line 45, the fluid friction of the medium MD in the conductive line 45 is equal to or lower than that of the medium MD in the filter 20.

Furthermore, when the mesh area ratio (S45/S20) is made almost equal to the ratio (S20a/S45a) of the entire area S20a of the filter 20 to the entire area S45a of the entire mesh of the conductive line 45, the meshes of the conductive line 45 can be made as fine as possible while making the fluid friction of the medium MD in the conductive line 45 almost equal to that of the medium MD in the filter 20. In this case, the contact area between the conductive line 45 and the medium MD can be made as large as possible while making the fluid friction of the medium MD in the conductive line 45 almost equal to that of the medium MD in the filter 20. As a result, it is possible to remove electric charges from the medium MD more efficiently.

According to the present embodiment, even when the cross-sectional area S20a of the filter 20 is small and the electrification amount of the medium MD is large, it is less likely to generate pin holes due to a surge in the pipe 32 because the conductive line 45 can remove electric charges from the medium MD. Therefore, the piping joint 40 and the semiconductor manufacturing apparatus 1 according to the present embodiment can realize reductions in the size of the filter 20 and in the cost of the filter 20 without taking the surge into much consideration.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A piping joint comprising:
a joint part configured to join a plurality of pipes for transporting a medium to one another;
at least one conductive line provided between the pipes so as to extend over cross-sections of the pipes; and
a ground part configured to ground the conductive line, wherein
the conductive line removes electric charges from the medium via the ground part.

2. The piping joint of claim 1, wherein a plurality of conductive lines are provided in a meshed manner or a net manner over the cross-sections of the pipes.

3. The piping joint of claim 1, wherein the joint part is formed by using a conductive material and electrically connects the conductive line to the ground part.

4. The piping joint of claim 2, wherein the joint part is formed by using a conductive material and electrically connects the conductive line to the ground part.

5. The piping joint of claim 1, wherein the conductive line is formed integrally with the joint part.

6. The piping joint of claim 1, wherein the conductive line is formed by using stainless steel.

7. The piping joint of claim 4, wherein the conductive line is formed by using stainless steel.

8. The piping joint of claim 2, wherein
the piping joint is arranged downstream of a filter configured to filter the medium, and
a mesh of the conductive lines is coarser than a mesh of the filter.

9. The piping joint of claim 2, wherein
the conductive lines are arranged downstream of a filter configured to filter the medium, and
a ratio S45/S20 of an area S45 of a mesh of the conductive lines to an area S20 of a mesh of the filter is almost equal to or higher than a reciprocal S20a/S45a of a ratio of an entire area S45a of an entire net of the conductive lines to an entire area S20a of the filter.

10. The piping joint of claim 1, wherein the conductive line is arranged downstream and near a filter configured to filter the medium, and the conductive line removes electric charges from the medium electrically charged by the filter.

11. The piping joint of claim 2, wherein the conductive line is arranged downstream and near a filter configured to filter the medium, and the conductive line removes electric charges from the medium electrically charged by the filter.

12. The piping joint of claim 10, wherein the piping joint is formed integrally with the filter.

13. The piping joint of claim 11, wherein the piping joint is formed integrally with the filter.

14. A semiconductor manufacturing apparatus comprising:
a filter configured to filter a medium;
a joint part arranged downstream of the filter, and configured to join a plurality of pipes for transporting the medium to one another;
at least one conductive line provided between the pipes so as to extend over cross-sections of the pipes; and
a ground part configured to ground the conductive line, wherein
the conductive line removes electric charges from the medium via the ground part.

15. The apparatus of claim 14, wherein a plurality of conductive lines are provided in a meshed manner or a net manner over the cross-sections of the pipes.

16. The apparatus of claim 14, wherein the joint part is formed by using a conductive material and electrically connects the conductive line to the ground part.

17. The apparatus of claim 14, wherein the conductive line is formed integrally with the joint part.

18. The apparatus of claim 15, wherein the piping joint is arranged downstream of a filter configured to filter the medium, and
a mesh of the conductive lines is coarser than a mesh of the filter.

19. The apparatus of claim 15, wherein
the conductive lines are arranged downstream of a filter configured to filter the medium, and
a ratio S45/S20 of an area S45 of a mesh of the conductive lines to an area S20 of a mesh of the filter is almost equal to or higher than a reciprocal S20a/S45a of a ratio of an entire area S45a of an entire net of the conductive lines to an entire area S20a of the filter.
